(19) United States
(12) Patent Application Publication
(10) Pub. No.: US 2009/0110848 A1
(43) Pub. Date: Apr. 30, 2009

(54) METHOD AND APPARATUS FOR HIGH-PRESSURE ATOMIC-BEAM LASER INDUCED DEPOSITION/ETCHING

(75) Inventors: James L. MAXWELL, Jemez Springs, NM (US); Robert W. SPRINGER, Los Alamos, NM (US)

Correspondence Address: HUSCH BLACKWELL SANDERS LLP, 720 OLIVE STREET, SUITE 2400, ST. LOUIS, MO, 63101, US

(73) Assignee: LOS ALAMOS NATIONAL SECURITY, LLC, Los Alamos, NM (US)

(21) Appl. No.: 11/923,788

(22) Filed: Oct. 25, 2007

(51) Int. Cl. C23C 16/48; C23C 16/44

(52) U.S. Cl. 427/596; 118/723 R

(57) ABSTRACT

A method for carrying out pulsed laser deposition is disclosed. The method comprises providing a target having a desired composition; irradiating the target with a pulsed laser beam to provide a plume of target material; and directing the plume in a desired direction by use of an inert carrier gas. The plume of target material is passed through an aperture to create an atomic beam. One or both of the plume or the atomic beam is irradiated to reduce the amount of agglomerated particles in the atomic beam. The atomic beam is directed onto a substrate to produce a deposition product. An apparatus for carrying out the method is also disclosed.

### STATEMENT REGARDING FEDERAL RIGHTS

This invention was made with government support under Contract No. DE-AC52-06NA25396 awarded by the U.S. Department of Energy. The government has certain rights in the invention.

### BACKGROUND OF INVENTION

The present application relates generally to atomic, molecular, and nanoparticle deposition techniques. More particularly, the application relates to high-pressure, atomic, molecular, and nanoparticle beam deposition.

A variety of methods for depositing thin-film coatings have been developed over the last half-century, including chemical vapor deposition, physical vapor deposition (e.g. sputtering, e-beam evaporation, IBAD, etc.), and pulsed laser deposition. Each has its advantages/disadvantages, depending on the material to be deposited, the substrate involved, and the desired material structure.

Of these coating methods, Pulsed Laser Deposition (PLD) has the advantage that materials can be stochiometrically-deposited, so that the composition of the target and deposit remain nearly identical. However, PLD has the disadvantage of “spall,” i.e. ejecting nano- to micro-scale particulates that travel with the plume to become embedded in the newly-formed deposit. And at high-pressures (i.e. atmospheric pressures and above), homogeneous nucleation tends to occur, where atoms within the plume recombine into nuclei, clusters, and aggregates. In addition, increasing the operating pressure and throughput of a PLD system tends to result in more recombination events. Ultimately, this limits the deposition rate and quality of the deposits that can be created by PLD systems.

Many different chemical vapor deposition (CVD) techniques exist, including Thermal CVD, plasma enhanced CVD, laser assisted CVD techniques, etc. All of these approaches use chemical precursors that decompose when exposed to elevated temperatures and/or electromagnetic fields—leaving behind a deposit material. The primary disadvantages of CVD methods are: (1) the deposition rate may be very slow, as the process is often maintained at low pressures to reduce homogeneous nucleation, (2) undesired byproducts can be incorporated into the deposit material, (3) obtaining a correct deposit stochiometry is difficult with multi-component systems, (4) the deposit uniformity, composition and crystal structure may depend strongly on the local substrate temperature or other process conditions, and (5) it is difficult (even with plasma enhanced CVD), to ensure that only certain chemical species are present during the reaction, which can influence the ultimate composition/structure of the deposit material. The growth of diamond vs. graphite is an important example, where the species present during the reaction directly influence the resulting crystal structure.

Accordingly, it would be desirable to provide a method and/or apparatus capable of conducting deposition and etching where specific atomic/molecular species can be directed at a substrate to produce a uniform deposit of desired composition and crystal structure—and at rapid rates. It would also be desirable to provide a method and/or apparatus capable of controlling the stochiometry of the deposit without introducing undesired spall-related particles/agglomerates and/or impurities at high deposition rates.

### SUMMARY OF INVENTION

One embodiment relates to an apparatus for carrying out laser-induced atomic/molecular beam deposition. The apparatus comprises: a chemical precursor delivery system with laser window, a target within the precursor delivery system, a first optic configured to direct a laser beam at the target, a first wall having a aperture, a substrate configured to receive an atomic/molecular beam, a second optic configured to direct a laser beam at either a point proximate to or at the aperture in the first wall, and a third (optional) optic, directing a laser beam at the point where the atomic/molecular beam impinges on the substrate.

Another embodiment relates to a method for carrying out laser-induced atomic/molecular beam deposition. The method comprises: (1) providing a flow of chemical precursor, (2) providing a target within the flow of chemical precursor, having a desired composition, (3) irradiating the target with a laser beam to provide a plume of target material, (4) directing the plume in a desired direction by use of the flow of chemical precursor, (5) passing the precursor and plume of target material through an aperture into a region of lower pressure, (6) irradiating the plume and precursor to create an atomic/molecular beam, (e.g. to reduce the amount of agglomerated particles in the plume or to partially decompose the precursor), (7) directing the atomic/molecular beam onto a substrate to produce a deposition product, and (8) (optional) irradiating the location where the atomic/molecular beam impinges on the substrate to further decompose the atomic/molecular beam or to produce a specific deposit composition, stochiometry, or crystal structure.

### BRIEF DESCRIPTION OF THE DRAWINGS

FIG. 1 is a schematic view of an apparatus for carrying out pulsed laser deposition.

### DETAILED DESCRIPTION

Using a focused short-pulse laser beam (i.e., less than about 1 fs to more than about 100 ps), a very high-temperature plasma is created at an aperture through which chemical precursors are flowing. While the chemical precursors are usually gases, they may also be liquids or super-critical fluids). These chemical precursors would typically be Chemical vapor deposition precursors or etchants, e.g. methane, trimethylamine alane, silane, chlorine, etc. Reactive gases, e.g. hydrogen or nitrogen, or inert carrier gases, such as Argon or Krypton may also be used. Adjacent to the aperture, a target comprised of a desired deposition material is placed such that a portion of the short-pulse beam is focused on the target and a plume of target material enters the flow of precursor/reactive/inert gases. Alternatively, nanoparticles of desired deposit material can be created through homogeneous nucleation using a laser beam in a separate chamber (e.g. through photolysis) and carried by the gas flow.

The plume is oriented such that it will not coat the laser window and/or the precursor delivery system more than necessary. The plume or nanoparticles of desired deposit material are carried along with the flow of precursor and pass through the aperture. A laser beam is focused near or at the aperture, such that some, if not all, molecular bonds are broken on the precursor/reactive gases, and particulates from the plume (or otherwise) are re-heated and potentially evaporated into their atomic components. Some components may be ionized, depending on the temperature.

During irradiation and while passing through the aperture into a region of relative vacuum, the precursor/plume becomes an atomic/molecular beam, where some of the (thermal) energy is converted into linear motion toward a target substrate or fiber to produce a deposition product. Specific species are produced in the atomic/molecular beam through the properties of the laser beam, the precursor flow rate, the aperture size, the pressure differential across the aperture, the precursors/materials used, etc. The potential for recombination to occur in the atomic/molecular beam is also controlled through similar parameters, so that, if desired, nanoparticles/clusters of specific composition and structure can be grown (or eliminated) in the beam.

Several apertures may be used to “align” this beam, so that the atomic/molecular beam motion is collimated—and the region were deposition occurs is limited (transverse to the beam). Where atomic/molecular ionized species are present, a magnetic field may be used to select particular species to pass through successive apertures, so that only particular species and/or particles may be present at the final deposition zone. Additional reactive gases may be added in subsequent chambers to form intermediate or desired species within this atomic/molecular beam.

Next, a bias voltage may be applied between the aperture (where the atomic/molecular beam is created) and the substrate/deposit material. In this way, species can be accelerated toward the substrate/deposit, such that they arrive with a desired energy, and the deposit can act as field-or thermionic-emission sources (e.g. when the deposit is in the form of fibers). Finally, a third laser beam (or a portion of the first/second beams) is directed at the location where the atomic/molecular beam impinges on the substrate/deposit—either to decompose any remaining precursors, desorb undesired by-products off the surface, re-evaporate forming nuclei within the molecular beam, induce the formation of a particular deposit microstructure by controlling the deposit temperature, etc.

One goal in designing an apparatus is to control the propagation distance of the beam; for example, if it is shorter than the time it takes for components within the beam to recombine into undesireable species/nuclei, such species/nuclei may not be present in the deposition product. More than one atomic beam can also be used to obtain multiple desired species at the reaction zone. One atomic beam can be split into several atomic beams for parallel deposition. Acoustic waves can also be used to separate species, retard or enhance the flow velocity at and beyond the aperture(s), etc. to create desired species or eliminate undesirable species.

Some benefits include a very high flux of materials along the atomic/molecular beam, so that very high deposition rates are possible. In addition, many disadvantages of the PLD and CVD techniques are eliminated, as species in the beam can be selected, homogeneous nucleation can be controlled, and undesired particulates can be broken into their atomic constituents within the atomic/molecular beam. In addition, optimal precursors and deposition compounds can be created within the atomic/molecular beam, such that particular stochiometries, compositions, and crystal structures can be created and undesired impurities and particulates are eliminated within the deposit material.

Consider, for example, the deposition of diamond-like carbon at high rates, using hydrogen as a carrier gas and methane or adamantane (for example) as precursor gases. The laser-heated plasma at the aperture will crack the hydrocarbon(s), and given the correct conditions, leave some sp³ bonded constituents in the gas flow. Using species selectivity, optimal species for diamond growth can be selected through the apertures—and accelerated toward the substrate/deposit. The hydrogen may also be decomposed into atomic hydrogen and selected through the apertures, enhancing the rate of graphite etching. This should allow diamond-like carbon and single-crystal diamond to be grown at large rates.

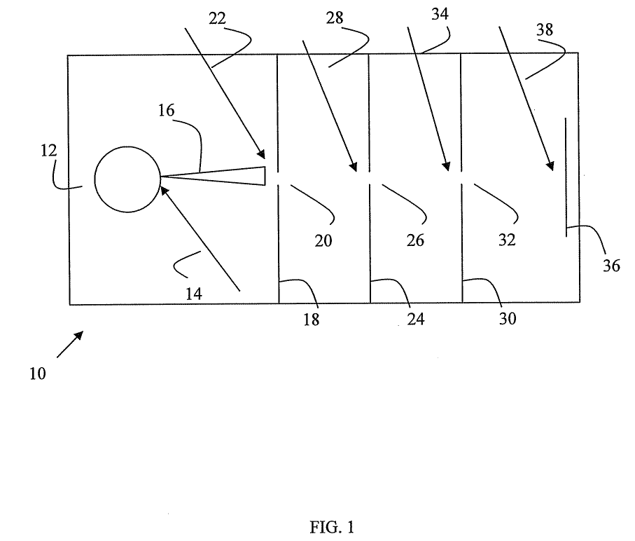

Referring to FIG. 1, apparatus 10 includes a target 12 that is irradiated with a pulsed laser beam 14. A plume of material 16 is ejected from the target which is configured such that plume 16 travels in the direction of wall 18. A carrier or precursor gas may be used to direct the flow of plume 16. Wall 18 includes an aperture 20 through which at least a portion of plume 16 may pass through. A second laser beam 22 is directed toward the aperture 20 to at least partially irradiate plume 16. While second laser beam 22 is directed at a point up stream of aperture 20, it may be desirable to direct another beam at a point on the downstream side of aperture 20. Alternatively, only a beam directed at a point on the downstream side of aperture 20 may be used. The region downstream of aperture 20 may be at a pressure lower than the region upstream of aperture 20 to accelerate the atomic beam. The carrier or precursor gas may be introduced through an aperture and directed in the direction of wall 18 and aperture 20.

The second laser beam 22 energizes the contents of plume 16 to break down agglomerates and nuclei resulting in an atomic or molecular beam. The beam passes between wall 18 and wall 24. In the region between walls 18 and 24, a reactive gas may be introduced into the atomic beam to change the composition of the beam. Again, wall 24 includes an aperture 26 and a third laser beam 28 may be directed toward the aperture 26 to at least partially irradiate the atomic beam. While third laser beam 28 is directed at a point up stream of aperture 26, it may be desirable to direct another beam at a point on the downstream side of aperture 26. Alternatively, only a beam directed at a point on the downstream side of aperture 26 may be used. The region downstream of aperture 26 may be at a pressure lower than the region upstream of aperture 26 to accelerate the atomic beam. In some embodiments, an electrical potential may be provided between wall 18 and wall 24 to accelerate or slow charged species. Also, a magnetic field may be used to divert charged species of a certain mass and velocity away from aperture 26, thus selecting what species will advance towards the substrate 36.

Another optional chamber is shown between walls 24 and 30. The atomic beam passes between wall 24 and wall 30. In the region between walls 24 and 30, a reactive gas may be introduced into the atomic beam to change the composition of the beam. Again, wall 30 includes an aperture 32 and a fourth laser beam 34 may be directed toward the aperture 32 to at least partially irradiate the atomic beam. While fourth laser beam 28 is directed at a point up stream of aperture 32, it may be desirable to direct another beam at a point on the downstream side of aperture 32. Alternatively, only a beam directed at a point on the downstream side of aperture 32 may be used. The region downstream of aperture 32 may be at a pressure lower than the region upstream of aperture 32 to accelerate the atomic beam. In some embodiments, an electrical potential may be provided between wall 24 and wall 30 to accelerate or slow charged species. Also, a magnetic field may be used to divert charged species of a certain mass and velocity away from aperture 32, thus selecting what species will advance towards the substrate 36.

The beam may exit the chamber between walls 24 and 30 through aperture 32. The atomic beam is then directed toward substrate 36 where fibers, thin films, and other useful structures may be grown. A fifth laser beam 38 (or portion of another beam) is directed at the substrate/fibers at the point of deposition. The fifth laser beam 38 may be used to decompose any remaining precursors, desorb undesired by-products off the surface, re-evaporate forming nuclei within the molecular beam, and/or to induce the formation of a particular deposit microstructure by controlling the deposit temperature.

While the apparatus is shown having three walls, other numbers may be used. A single wall may be used in conjunction with a laser beam such as beam 38 directed to a point near the point of deposition. Alternatively, a greater number of walls may be used to provided additional chambers for the introduction of reactive gasses.

What is claimed is:

1. An apparatus for carrying out atomic or molecular beam deposition, the apparatus comprising:
a precursor delivery system;
a target within the precursor delivery system;
a first optic configured to direct a laser beam at the target;
a first wall having an aperture;
a substrate configured to receive an atomic and/or molecular beam; and
a second optic configured to direct a laser beam at a point proximate to the aperture in the first wall, used to generate an atomic and/or molecular beam.

2. The apparatus of claim 1, wherein the apparatus is configured to provide an electrical potential between the first wall and the substrate.

3. The apparatus of claim 1, further comprising a third optic configured to direct a laser beam at a point proximate to the substrate.

4. The apparatus of claim 1, further comprising a second wall having an aperture.

5. The apparatus of claim 4, further comprising a third optic configured to direct a laser beam at a point proximate to the aperture in the second wall.

6. The apparatus of claim 1, further comprising a fourth optic configured to direct a laser beam at a point proximate to the substrate and the second optic is configured to direct a laser beam at a point proximate to the aperture in the first wall.

7. The apparatus of claim 4, wherein the apparatus is configured to introduce a reactive gas into the region between the first wall and the second wall.

8. A method for carrying out atomic or molecular beam deposition, the method comprising:
providing a flow of precursor(s);
providing a target having a desired composition;
irradiating the target with a pulsed laser beam to provide a plume of target material;
directing the plume in a desired direction by use of the flow of precursors;
passing the flow of precursors and plume of target material through an aperture;
irradiating the flow of precursors and plume of target material to create an atomic or molecular beam; and
directing the atomic or molecular beam onto a substrate to produce a deposition product.

9. The method of claim 8, wherein the deposition product is a fiber or a thin film.

10. The method of claim 8, further comprising passing the atomic beam through a second aperture.

11. The method of claim 10, further comprising irradiating the beam a second time.

12. The method of claim 11, further comprising adding a reactive gas to the atomic beam.

13. The method of claim 12, wherein the reactive gas comprises a hydrocarbon.

14. The method of claim 8, further comprising selectively removing species from the atomic beam by us of an applied magnetic field.

15. A deposition product produced according to the method of claim 8.

16. The deposition product of claim 17, wherein the deposition product comprises a fiber.

17. The deposition product of claim 17, wherein the deposition product comprises a thin film.

18. The deposition product of claim 17, wherein the thin film comprises diamond.

19. A method for carrying out atomic or molecular beam deposition, the method comprising:
providing a flow of precursor(s);
providing a target having a desired composition;
irradiating the target with a laser beam to provide a plume of target material;
directing the plume in a desired direction by use of the flow of precursors;
passing the flow of precursors and plume of target material through an aperture;
irradiating the flow of precursors and plume of target material with a second laser beam to create an atomic or molecular beam;
directing the atomic or molecular beam onto a substrate to produce a deposition product; and
directing a third laser beam at a point proximate to where the atomic or molecular beam impinges on the substrate.
